(19) United States
(12) Patent Application Publication
(10) Pub. No.: US 2021/0027138 A1
(43) Pub. Date: Jan. 28, 2021

(54) RESERVOIR COMPUTING NETWORKS USING OSCILLATORS

(71) Applicant: SanDisk Technologies LLC, Addison, TX (US)

(72) Inventors: Daniel Bedau, San Jose, CA (US); Wen Ma, San Jose, CA (US)

(73) Assignee: SanDisk Technologies LLC, Addison, TX (US)

(21) Appl. No.: 16/880,136

(22) Filed: May 21, 2020

Related U.S. Application Data
(60) Provisional application No. 62/877,505, filed on Jul. 23, 2019.

(51) Int. Cl. G06N 3/04; H01L 47/00; H03B 7/00; G06N 3/063; G06N 3/08

(52) U.S. Cl. CPC G06N 3/0445; H01L 47/00; G06N 3/08; G06N 3/0635; H03B 7/00

(57) ABSTRACT

A reservoir computing system comprising an input layer configured to receive input data from a signal propagation channel and to convert the input data into fixed input values, a reservoir configured to receive the fixed input values and generate a set of trained output values, and an output layer configured to receive the set of trained output values and generate a probability distribution based on the set of trained output values. The reservoir is comprised of a plurality of integrated oscillator components coupled in a fixed, random network, wherein each of the oscillator components is comprised of a device characterized by a current-voltage curve that comprises a region of non-linear behavior, such as a negative differential resistance (NDR) behavior.

### TECHNICAL FIELD

This disclosure relates to neuromorphic computing systems and in particular reservoir computing networks using compact, high-frequency oscillators that comprise materials having certain electrical properties or behaviors under specific operating conditions. In addition, the present disclosure relates to feedback control mechanisms for optimizing the performance of reservoir computing systems, as well as applications for reservoir networks with respect to a multitude of signal propagation channels.

### BACKGROUND

A technological revolution in computational capabilities in recent decades is in part a result of the symbiotic relationship between vast improvements in computational power, device connectivity, and the ability to acquire and store an enormous amount of data. In order to meaningfully organize, process, search, analyze, form models and/or projections, and otherwise utilize the sheer amounts of data being captured, there is, in turn, significant improvements and enhancements being made to conventional computing and programming system architectures. However, despite these advances, such systems are not comparable to the unequaled processing capabilities of the human brain with respect to certain analytical tasks such as classifying, recognizing, predicting, and reacting. Accordingly, there is substantial momentum towards developing more dynamic computational models that are machine-powered and progressively trainable as made possible by the abundance of data collection. Such computational models include, for example, artificial neural networks and convolutional neural networks. However, because these models employ digital computing systems and, as a result, they place significant burdens on machine processor components, there are finite limitations to their capabilities and applicability as a result of the intrinsic constraints in power, performance and speed, and the associated costs. Therefore, there is a significant eagerness to study and harness machine behaviors that, due to physical principles, inherently imitate brain-like neural activity. Some examples of such “neuromorphic” components include semiconductor-based oscillators that mimic the oscillatory or spiking nature of human neural conductivity and stimulus. Such oscillators may function discretely or can be coupled to form powerful and synchronized information processing and analyzing networks.

As mentioned above, artificial neural networks are an increasingly prevalent machine learning technique for applications such as image classification or object detection, or for processing sequential or time-series data (such as audio and video streams), including in connection with speech recognition, machine translation, and time-series prediction. While existing neural network machine learning architectures, such as CMOS-based von Neumann engines, may achieve satisfactory performance and improved energy efficiency, they require significant training costs due to, for example, their requisite large-scale model sizes. Comparatively speaking, nature demonstrates that similar tasks can be carried out in the human brain using less than one-thousandth of the power.

Accordingly, different neuromorphic computational schemes have been proposed for performing high energy efficiency computations. For example, reservoir computing systems present an alternative approach to the existing neural network configurations (such as recurrent neural networks (RNNs, LSTMs, etc.)). Generally speaking, reservoir computing systems typically include liquid state machines for utilizing the neuronal spiking information, as well as an echo state network for utilizing analog values. In certain reservoir computing systems, the hardware components may include optical components, resistive switching devices, spintronic oscillators, other suitable components, or a combination thereof. However, with respect to reservoir computing systems that comprise oscillators, it is a difficult challenge to fabricate a network of a large number of coupled oscillators, as the oscillators tend to require a relatively significant amount of space due to their frequency determining elements, such as inductors and/or capacitors. Therefore, there is a significant level of motivation to determine alternative nano-scale oscillator types and configurations that are scalable and can be adeptly electrically coupled for high density applications.

### SUMMARY

Various embodiments include a signal-producing oscillating circuit that comprises a negative differential resistance (NDR) device characterized by a current-voltage curve that comprises a region in which an increasing input voltage corresponds to a decreasing current condition. Additionally, the oscillating circuit may comprise a current-drive switching element that is electrically coupled to the negative differential resistance (NDR) device and has a resistance-switching state that, in response to the decreasing current condition, produces an increase in current that induces the circuit to oscillate and produce an oscillatory signal.

Other embodiments include a reservoir comprising a plurality of integrated oscillator components coupled to one another in a fixed, random network, wherein each of the oscillator components is comprised of a device characterized by a current-voltage curve that comprises a region of non-linear behavior.

Additional embodiments include a reservoir computing system that comprises an input layer configured to receive input data from a signal propagation channel and to convert the input data into one or more fixed input values, a reservoir configured to receive the one or more fixed input values and to generate one of a set of trained output values, and an output layer configured to receive the one of the set of trained output values and to generate one of at least a probability distribution based on the one of the set of trained output values.

### BRIEF DESCRIPTION OF THE DRAWINGS

A more detailed description is set forth below with reference to example embodiments depicted in the appended figures. Understanding that these figures depict only example embodiments of the disclosure and are, therefore, not to be considered limiting of its scope, the disclosure is described and explained with added specificity and detail through the use of the accompanying drawings in which:

FIG. 1 is a graphical representation of a neuromorphic reservoir computing system, in accordance with exemplary embodiments;

FIG. 2A generally depicts a region of the I-V curve of a “s”-type NDR element, in accordance with exemplary embodiments;

FIG. 2B generally depicts a region of the I-V curve of an “n”-type NDR element, in accordance with exemplary embodiments;

FIG. 3A is a schematic representation of an oscillator circuit comprising a 2^{nd} order circuit element that is made oscillatory through the negative damping from an NDR element therein;

FIG. 3B depicts a region of the I-V curve of the oscillator circuit of FIG. 3A, in accordance with exemplary embodiments;

FIG. 4A is a schematic representation of a current-driven switching element, in accordance with exemplary embodiments;

FIG. 4B illustrates the oscillating behavior of a resulting circuit in which a switching element (e.g., the switching element in FIG. 4A) is coupled to an oscillator circuit (e.g., the oscillator circuit in FIG. 3A), in accordance with exemplary embodiments;

FIG. 4C depicts a region of the I-V curve of the oscillator circuit of FIG. 3A when coupled to a switching element, in accordance with exemplary embodiments;

FIG. 4D is a schematic representation of an oscillator unit that comprises an NDR element in series with a switching element, with two load lines depicting the two states of the switching element, in accordance with exemplary embodiments;

FIG. 5A generally depicts a band diagram of a p-n junction of a tunnel diode in an unbiased state, and with FIG. 5B depicting its corresponding location along the associated I-V curve, in accordance with exemplary embodiments;

FIGS. 5C and 5D depict, respectively, a band diagram and the corresponding location along the I-V curve of the p-n junction of FIG. 5A while under an initial applied voltage, in accordance with exemplary embodiments;

FIGS. 5E and 5F depict, respectively, a band diagram and the corresponding location along the I-V curve of the p-n junction of FIG. 5A while under an increased applied voltage, in accordance with exemplary embodiments;

FIGS. 5G and 5H depict, respectively, a band diagram and the corresponding location along the I-V curve of the p-n junction of FIG. 5A while under a further increase in the applied voltage, in accordance with exemplary embodiments;

FIGS. 5I and 5J depict, respectively, a band diagram and the corresponding location along the I-V curve of the p-n junction of FIG. 5A while under even a further increase in the applied voltage in which the tunnel current has dropped to zero, in accordance with exemplary embodiments;

FIG. 6A schematically depicts a tunnel diode structure fabricated on a semiconductor substrate material, in accordance with an exemplary embodiment;

FIG. 6B schematically depicts a tunnel diode structure fabricated on a semiconductor substrate material, in accordance with another exemplary embodiment;

FIG. 7 schematically depicts a cross-section of an exemplary portion of a coupled oscillator network, in accordance with an exemplary embodiment;

FIG. 8 schematically depicts a cross-section of an exemplary portion of an oscillator network using a transistor configuration to achieve the coupling, in accordance with another exemplary embodiment;

FIG. 9 schematically depicts the circuitry integrating a single cell of a reservoir, in accordance with exemplary embodiments;

FIG. 10 is a graphical representation of a time-multiplexed neuromorphic reservoir computing system, in accordance with exemplary embodiments;

FIG. 11A depicts a characteristic energy gap (E_{g}) separating the valence and the conduction bands formed by the interaction energy (U) in a Mott insulator material, in accordance with exemplary embodiments;

FIG. 11B is a schematic illustration of the energy levels of a Mott insulator material, in accordance with exemplary embodiments;

FIG. 12 illustrates the metal-insulator transition (MIT) of a Mott insulator material, in accordance with exemplary embodiments;

FIG. 13 is a graphical illustration of the large-scale change in resistance of a Mott insulator material in response to the temperature, in accordance with exemplary embodiments;

FIG. 14 is a graphical depiction of the resistance and transition temperature of a Mott insulator material in relationship to doping, in accordance with exemplary embodiments;

FIG. 15 is a schematic representation of an oscillator circuit comprised of a transition metal oxide element in series with a resistor, in accordance with exemplary embodiments;

FIG. 16 generally depict the characteristic nonlinearity from the perspective of an associated I-V curve of a transition metal oxide, in accordance with exemplary embodiments;

FIG. 17 generally depicts the oscillatory behavior of an oscillator circuit comprised of a transition metal oxide (e.g., the circuit of FIG. 15) according to various measurements, in accordance with exemplary embodiments;

FIG. 18 is a graphical representation of a neuromorphic reservoir computing system, in accordance with other exemplary embodiments;

FIG. 19A generally illustrates a spoken digit recognition training schematic in accordance with principles of the present disclosure;

FIG. 19B illustrates a % accuracy of the spoken digit recognition training scheme according to FIG. 19A;

FIG. 20A generally illustrates an MNIST stroke sequence classification training schematic in accordance with principles of the present disclosure;

FIG. 20B illustrates a % accuracy of the MNIST stroke sequence classification training scheme according to FIG. 20A;

FIG. 21 generally illustrates waveforms according to principles of the present disclosure.

FIG. 22 generally illustrates a training schematic for an HDD series according to principles of the present disclosure;

FIG. 23 generally illustrates a reservoir of a reservoir computing system having a feedback mechanism, in accordance with exemplary embodiments;

FIG. 24 generally illustrates a reservoir of a reservoir computing system separated into distinct feedback control regions, in accordance with exemplary embodiments;

FIG. 25 generally illustrates a system architecture for tuning identical reservoirs in parallel, in accordance with exemplary embodiments; and

FIG. 26 generally illustrates a bipartite reservoir having interleaved components for tuning, in accordance with exemplary embodiments.

### DETAILED DESCRIPTION

The following description is directed to various exemplary embodiments of the disclosure. Although one or more of these embodiments may be preferred, the embodiments disclosed should not be interpreted, or otherwise used, as limiting the scope of the disclosure, including the claims. In addition, one skilled in the art will understand that the following description has broad application, and the detailed explanation of any specific embodiment is meant only to be exemplary of that embodiment and is not intended to suggest that the scope of the disclosure, including the claims, is limited to that particular embodiment.

The several aspects of the present disclosure may be embodied in the form of an apparatus, system, method, or computer program process. Therefore, aspects of the present disclosure may be entirely in the form of a hardware embodiment or a software embodiment (including but not limited to firmware, resident software, micro-code, or the like), or may be a combination of both hardware and software components that may generally be referred to collectively as a “circuit,” “module,” “apparatus,” or “system.” Further, various aspects of the present disclosure may be in the form of a computer program process that is embodied, for example, in one or more non-transitory computer-readable storage media storing computer-readable and/or executable program code.

Additionally, various terms are used herein to refer to particular system components. Different companies may refer to a same or similar component by different names and this description does not intend to distinguish between components that differ in name but not in function. To the extent that various functional units described in the following disclosure are referred to as “modules,” such a characterization is intended to not unduly restrict the range of potential implementation mechanisms. For example, a “module” could be implemented as a hardware circuit that comprises customized very-large-scale integration (VLSI) circuits or gate arrays, or off-the-shelf semiconductors that include logic chips, transistors, or other discrete components. In a further example, a module may also be implemented in a programmable hardware device such as a field programmable gate array (FPGA), programmable array logic, a programmable logic device, or the like. Furthermore, a module may also, at least in part, be implemented by software executed by various types of processors. For example, a module may comprise a segment of executable code constituting one or more physical or logical blocks of computer instructions that translate into an object, process, or function. Also, it is not required that the executable portions of such a module be physically located together, but rather, may comprise disparate instructions that are stored in different locations and which, when executed together, comprise the identified module and achieve the stated purpose of that module. The executable code may comprise just a single instruction or a set of multiple instructions, as well as be distributed over different code segments, or among different programs, or across several memory devices, etc. In a software, or partial software, module implementation, the software portions may be stored on one or more computer-readable and/or executable storage media that include, but are not limited to, an electronic, magnetic, optical, electromagnetic, infrared, or semiconductor-based system, apparatus, or device, or any suitable combination thereof. In general, for purposes of the present disclosure, a computer-readable and/or executable storage medium may be comprised of any tangible and/or non-transitory medium that is capable of containing and/or storing a program for use by or in connection with an instruction execution system, apparatus, processor, or device.

Similarly, for the purposes of the present disclosure, the term “component” may be comprised of any tangible, physical, and non-transitory device. For example, a component may be in the form of a hardware logic circuit that is comprised of customized VLSI circuits, gate arrays, or other integrated circuits, or is comprised of off-the-shelf semiconductors that include logic chips, transistors, or other discrete components, or any other suitable mechanical and/or electronic devices. In addition, a component could also be implemented in programmable hardware device such as field programmable gate arrays (FPGA), programmable array logic, programmable logic devices, etc. Furthermore, a component may be comprised of one or more silicon-based integrated circuit devices, such as chips, die, die planes, and packages, or other discrete electrical devices, in an electrical communication configuration with one or more other components via electrical conductors of, for example, a printed circuit board (PCB) or the like. Accordingly, a module, as defined above, may in certain embodiments, be embodied by or implemented as a component and, in some instances, the terms module and component may be used interchangeably.

Where the term “circuit” is used herein, it comprises one or more electrical and/or electronic components that constitute one or more conductive pathways that allow for electrical current to flow. A circuit may be in the form of a closed-loop configuration or an open-loop configuration. In a closed-loop configuration, the circuit components may provide a return pathway for the electrical current. By contrast, in an open-looped configuration, the circuit components therein may still be regarded as forming a circuit despite not including a return pathway for the electrical current. For example, an integrated circuit is referred to as a circuit irrespective of whether the integrated circuit is coupled to ground (as a return pathway for the electrical current) or not. In certain exemplary embodiments, a circuit may comprise a set of integrated circuits, a sole integrated circuit, or a portion of an integrated circuit. For example, a circuit may include customized VLSI circuits, gate arrays, logic circuits, and/or other forms of integrated circuits, as well as may include off-the-shelf semiconductors such as logic chips, transistors, or other discrete devices. In a further example, a circuit may comprise one or more silicon-based integrated circuit devices, such as chips, die, die planes, and packages, or other discrete electrical devices, in an electrical communication configuration with one or more other components via electrical conductors of, for example, a printed circuit board (PCB). A circuit could also be implemented as a synthesized circuit with respect to a programmable hardware device such as a field programmable gate array (FPGA), programmable array logic, and/or programmable logic devices, etc. In other exemplary embodiments, a circuit may comprise a network of non-integrated electrical and/or electronic components (with or without integrated circuit devices). Accordingly, a module, as defined above, may in certain embodiments, be embodied by or implemented as a circuit.

It will be appreciated that example embodiments that are disclosed herein may be comprised of one or more microprocessors and particular stored computer program instructions that control the one or more microprocessors to implement, in conjunction with certain non-processor circuits and other elements, some, most, or all of the functions disclosed herein. Alternatively, some or all functions could be implemented by a state machine that has no stored program instructions, or in one or more application-specific integrated circuits (ASICs) or field programmable gate arrays (FPGAs), in which each function or some combinations of certain of the functions are implemented as custom logic. A combination of these approaches may also be used. Further, any references below to a “controller” shall be defined as comprising individual circuit components, an application-specific integrated circuit (ASIC), a microcontroller with controlling software, a digital signal processor (DSP), a field programmable gate array (FPGA), and/or a processor with controlling software, or combinations thereof.

Additionally, the terms “program,” “software,” “software application,” and the like as may be used herein, refer to a sequence of instructions that is designed for execution on a computer-implemented system. Accordingly, a “program,” “software,” “application,” “computer program,” or “software application” may include a subroutine, a function, a procedure, an object method, an object implementation, an executable application, an applet, a servlet, a source code, an object code, a shared library/dynamic load library and/or other sequence(s) of specific instructions that is designed for execution on a computer system.

Further, the terms “couple,” “coupled,” or “couples,” where may be used herein, are intended to mean either a direct or an indirect connection. Thus, if a first device couples, or is coupled to, a second device, that connection may be way of a direct connection or through an indirect connection via other devices (or components) and connections.

Regarding the use herein of terms such as “an embodiment,” “one embodiment,” an “exemplary embodiment,” a “particular embodiment,” or other similar terminology, these terms are intended to indicate that a specific feature, structure, function, operation, or characteristic described in connection with the embodiment is found in at least one embodiment of the present disclosure. Therefore, the appearances of phrases such as “in one embodiment,” “in an embodiment,” “in an exemplary embodiment,” etc., may, but do not necessarily, all refer to the same embodiment, but rather, mean “one or more but not all embodiments” unless expressly specified otherwise. Further, the terms “comprising,” “having,” “including,” and variations thereof, are used in an open-ended manner and, therefore, should be interpreted to mean “including, but not limited to . . . ” unless expressly specified otherwise. Also, an element that is preceded by “comprises . . . a” does not, without more constraints, preclude the existence of additional identical elements in the subject process, method, system, article, or apparatus that comprises the element.

The terms “a,” “an,” and “the” also refer to “one or more” unless expressly specified otherwise. In addition, the phrase “at least one of A and B” as may be used herein and/or in the following claims, whereby A and B are variables indicating a particular object or attribute, indicates a choice of A or B, or both A and B, similar to the phrase “and/or.” Where more than two variables are present in such a phrase, this phrase is hereby defined as including only one of the variables, any one of the variables, any combination (or sub-combination) of any of the variables, and all of the variables.

Further, where used herein, the term “about” or “approximately” applies to all numeric values, whether or not explicitly indicated. These terms generally refer to a range of numeric values that one of skill in the art would consider as being equivalent to the recited values (e.g., having the same function or result). In certain instances, these terms may include numeric values that are rounded to the nearest significant figure.

In addition, any enumerated listing of items that is set forth herein does not imply that any or all of the items listed are mutually exclusive and/or mutually inclusive of one another, unless expressly specified otherwise. Further, the term “set,” as used herein, shall be interpreted to mean “one or more,” and in the case of “sets,” shall be interpreted to mean multiples of (or a plurality of) “one or mores,” “ones or more,” and/or “ones or mores” according to set theory, unless otherwise expressly specified otherwise.

In the detailed description that follows, reference is made to the appended drawings, which form a part thereof. It is recognized that the foregoing summary is illustrative only and is not intended to be limiting in any manner. In addition to the illustrative aspects, example embodiments, and features described above, additional aspects, exemplary embodiments, and features will become apparent by reference to the drawings and the detailed description below. The description of elements in each figure may refer to elements of proceeding figures. Like reference numerals may refer to like elements in the figures, including alternate exemplary embodiments of like elements.

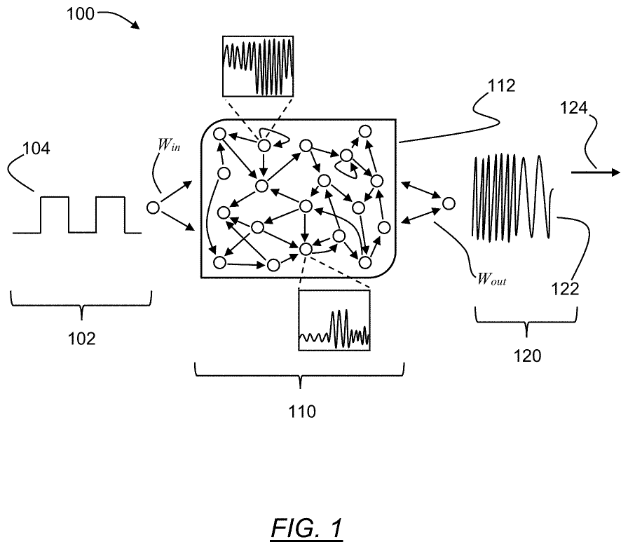

Referring now to the drawings in detail and beginning with FIG. 1, there is depicted a high-level diagram of an exemplary embodiment of a reservoir computing system 100. In this particular embodiment, the reservoir computing system 100 is generally comprised of an input layer 102 configured to receive a set of input data, such as input data signal 102, and to convert the input data into fixed input values (Wᵢₙ), or vectors. As depicted, a dynamic reservoir 110 receives the fixed input values (Wᵢₙ) and, subsequently, generates one of a set of trained output values (Wₒᵤₜ), or a set of random output vectors. Further, the reservoir computing system 100 comprises an output layer 120 that is configured to receive the one of the set of trained output values (Wₒᵤₜ), or set of random output vectors, and to generate, for example, a probability distribution based on the one of the set of trained output values (Wₒᵤₜ), or set of random output vectors. In some exemplary embodiments, the reservoir computing system 100 is configured to output a random set of output vectors to a machine learning phase, such as a single perceptron layer 124. Subsequently, the perceptron layer 124 is trained for a desired result according to a series of output signal(s) or “teaching” signal(s) 122, resulting in the ability to, for example, classify the data. As described in further detail below, reservoir 110 may be comprised of a plurality of oscillators 112 coupled to one another according to a fixed and random network, wherein the network is configured to be scalable, as is particularly beneficial with respect to neuromorphic computing applications. As such, the oscillatory nature of the reservoir 110 produces a bio-inspired machine learning approach that operates in a manner similar to how the human brain processes information and generates patterns of transient neuronal activity that is excited by input sensory signals.

Importantly, the input layer 102 may comprise a multitude of data channels in parallel with one another.

In some embodiments, the systems described herein, may be configured to provide desirable performance during specific benchmark tasks that include, for example, speech recognition, handwritten digit recognition, and memory drive (e.g., hard disk drive (HDD)) channel decoding, wherein the reservoir computing may provide a reduction in power consumption, inference speed, and footprint compared to, for example, CPU, GPU, FPGA, and other nano-device based reservoir computing systems.

Oscillator Circuit Comprising A Negative Differential Resistance (NDR) Device

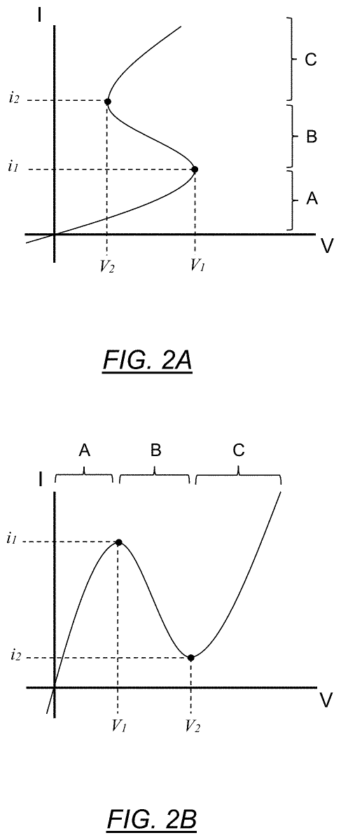

As described above, the reverberation and input-output mapping mechanism by which the reservoir 110 operates may comprise a network of oscillators 112. There are a multitude of electronic components that can produce oscillations or can be harmonically induced to oscillate. Of particular interest are electrical components that are tiny in scale and comprised of materials having elemental electrical conductivity properties that, when harnessed effectively and under certain operating conditions (e.g., when a certain voltage/current bias is applied), generate very high frequency oscillations using a low power consumption. One exemplary class of integrated devices well-suited for oscillator circuits having these objectives are devices that comprise electrical components that exhibit a negative differential resistance (NDR) behavior. More specifically, a device that exhibits NDR behavior is characterized as having a region along its respective current-voltage characteristic curve, or I-V curve, in which, under certain operating conditions, the device experiences a differential resistance that is negative (R_{diff}<0), such that a rise in current or voltage across the device results in a decrease in the voltage or current, respectively, as dictated by Ohm's Law. Further, the NDR region can fluctuate as, at a certain biasing condition, this region becomes unstable and the device swiftly switches to a stable operating condition in which the differential resistance returns to a positive value (R_{diff}>0). In general terms, such NDR devices may be classified into two different types, namely, “current-controlled” and “voltage-controlled.” FIG. 2A depicts the characteristic behavior of a “current-controlled” NDR-type device from the viewpoint of its associated I-V curve. The I-V curve can generally be divided into three principal regions, which are marked for reference in FIG. 2A as regions A, B, and C. Beginning with region A, an initial increase in current through the device results in a corresponding increase in voltage across the device. However, in region B, as the current approaches a certain threshold value (i₁), the device begins to experience a negative differential resistance (R_{diff}<0), thereby resulting in a lower voltage across the device (V<V₁). In region C, as the current continues to increase, the voltage across the device returns to an increasing level (V>V₂) once the current reaches a second threshold value (i₂). Consequently, this type of NDR device may be referred to as a “s-type” NDR device due to the distinctive “s”-shape of its associated I-V curve.

Similarly, FIG. 2B depicts the characteristic behavior of a “voltage-controlled” NDR device from the perspective of its associated I-V curve, which takes on a relatively “n”-shape. Here too, the I-V curve can be considered to have three distinct operating regions, which are marked for reference in FIG. 2B as regions A, B, and C. In region A, increasing low voltages initially correspond to an increase in the current flowing through the device, as is expected. However, as the voltage approaches a certain threshold level (V₁), the current flow through the device begins to actually decrease (I<i₁) as the device experiences a negative differential resistance (R_{diff}<0). This constitutes region B. Yet, in region C, once the increasing voltage reaches a second threshold value (V₂), the increasing voltage causes a corresponding increase in the current passing through the device (I>i₂), thus returning to a more conventional operation. This second type of NDR device may be referred to as an “n-type” NDR device, due to the particular shape of its associated I-V curve.

Accordingly, by incorporating an NDR device into a circuit and applying particular biasing conditions thereto, this fluctuating electrical behavior of the NDR device can be advantageously utilized to produce an oscillating circuit that will generate, for example, a repetitive output signal. Therefore, any device that exhibits NDR behavior may be suitable for such an application. Some components that are known to exhibit an NDR behavior include, but are not limited to, discharges, varistors, tunnel diodes, and magnetic junctions.

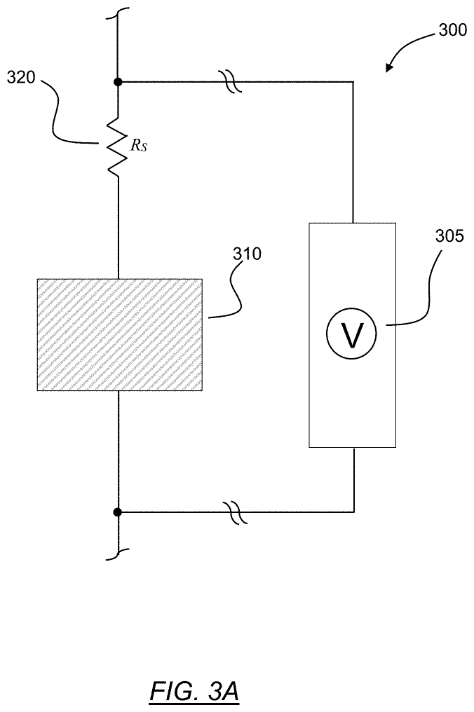

Referring now to FIG. 3A, depicted is a high-level schematic representation of an exemplary embodiment of an oscillator circuit 300, according to one possible configuration. In this particular embodiment, oscillator circuit 300 comprises a voltage-driven “n-type” NDR element 310 and a linear resistive switching element 320 (R_{S}) placed in series with the NDR element 310. Further, the NDR element 310 and the resistor 320 are electrically coupled to a variable voltage source (V) 305.

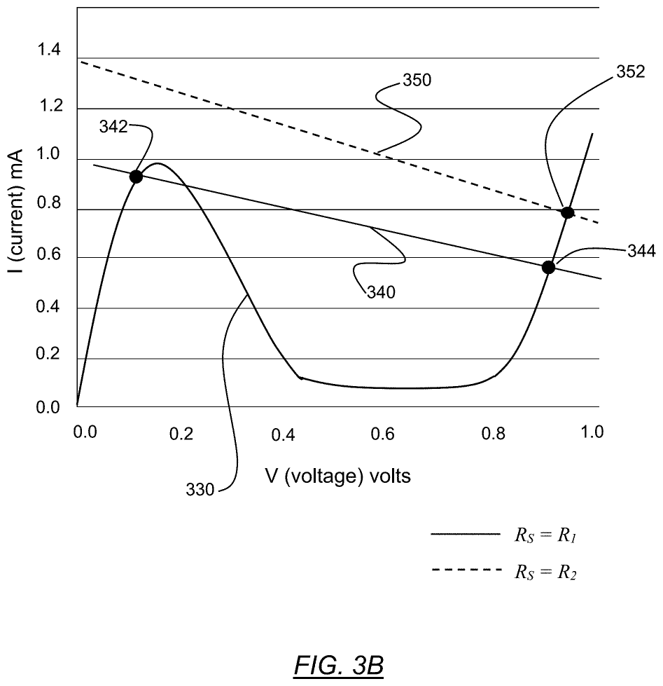

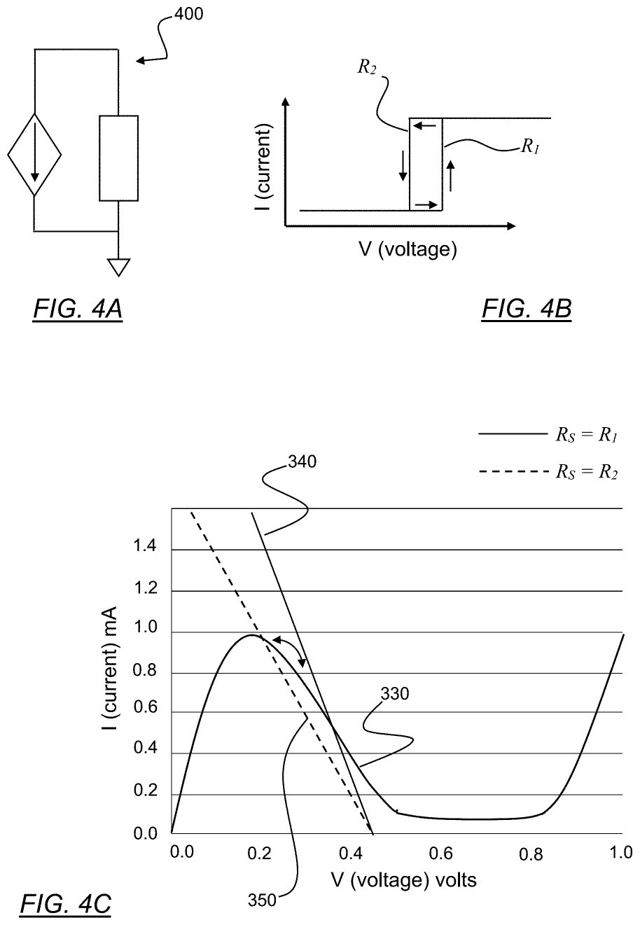

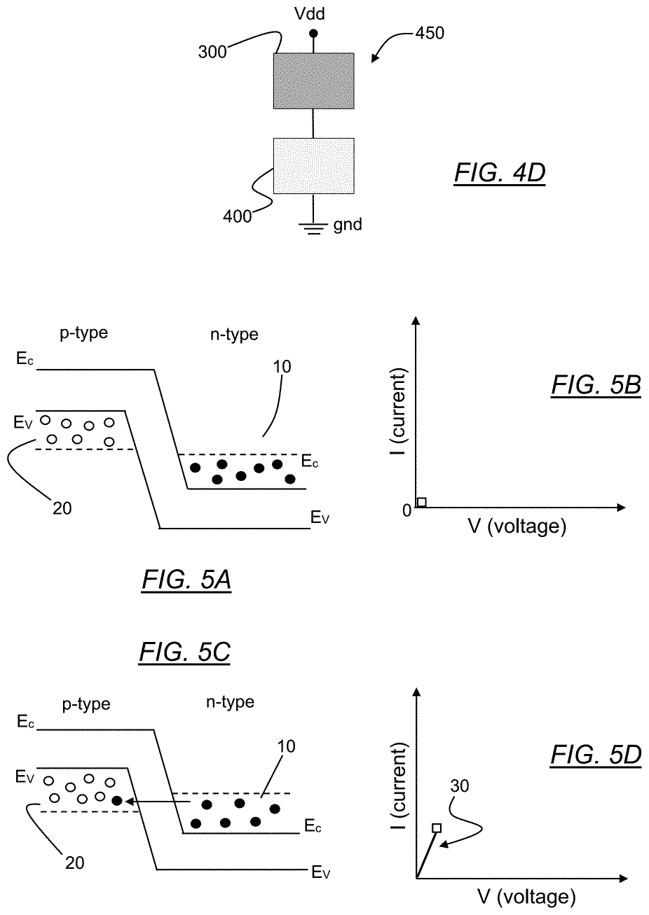

In FIG. 3B, there is shown an I-V curve that, in general terms, illustrates the NDR behavior of the oscillator circuit 300 depicted in FIG. 3A, under an arbitrary set of biasing conditions selected for illustrative purposes only. Accordingly, the horizontal axis in FIG. 3B indicates the voltage applied to the circuit and the vertical axis indicates the resultant current through the NDR element 310. As shown, the NDR behavior region 330, in which the current experiences a decrease despite the increasing input voltage, occurs as the voltage increases between approximately 0.17V and 0.5V. However, once the input voltage increases beyond approximately 0.5V, the decreasing direction of the current ceases and the current returns to increasing in value once again. Also depicted in FIG. 3B are two exemplary load lines 340 and 350, with each load line 340, 350 representing the relationship between the current and voltage (according to Ohm's Law) according to a respective resistance value (R_{S}) of the resistor 320. As such, load line 340 represents the permitted current and voltage combinations directed by, for example, a resistance value R₁. Correspondingly, load line 350 represents the permitted current and voltage combinations directed by, for example, a resistance value R₂, wherein R₁ does not equal R₂. As is shown, where R_{S} equals R₁, load line 340 intersects the I-V curve of the NDR element 310 at three points. Two of the intersection points, 342 and 344, are stable, thereby allowing for a bi-stable system. However, where R_{S} equals R₂, there exists only a single stable intersection point 352 with the NDR element's I-V curve. Therefore, by selecting the resistance values R₁ and R₂ such that their respective load lines will intersect the I-V curve along a segment of the NDR region 330 in which the current is decreasing, the oscillator circuit 300 can be made to, theoretically, infinitely oscillate between load lines in a manner similar to a feedback or compensation loop by coupling the NDR element 310 to a switching element that switches between resistance values R₁ and R₂ under certain operating conditions. In some exemplary embodiments, the switching element may comprise a current-driven switch, such as a magnetic tunnel junction or a GMR device. The schematic diagram in FIG. 4A depicts, generally, an electrical representation of a suitable current-driven switch 400 according to an exemplary embodiment thereof. Further, FIGS. 4B and 4C diagrammatically illustrate the oscillating (or looping) operation of the switching element 400 from the perspective of the current/voltage relationship (FIG. 4B) and its interaction with, and dependency on, the paradoxical behavior of the NDR region 330 of the NDR element's I-V curve (FIG. 4C). As best seen in FIG. 4C, as the voltage is increasing, thereby causing the current initially increase, the switch begins in a high current state (at low resistance). As the increasing voltage enters the NDR region 330 of the I-V curve and the current begins to decrease, this current drop causes the switching element 400 to switch to a low current state in which a larger voltage drop is experienced across the switching element 400. This low current-low voltage condition causes a shift in the resistance value, as indicated by a corresponding jump to load line 350, wherein load line 350 is associated with resistance value R₂. However, as dictated by the NDR region 330 of the I-V curve, this jump results in the system returning to the high current-low voltage state, which will again trigger the switching element 400 to switch to a low current state as the input voltage increases, thereby repeating this circular process infinitely. The diagram set forth in FIG. 4B depicts the shift in resistance and the continual looping between a high voltage, low current condition and a low current, high voltage condition. Essentially, NDR element 310 provides gain (or, alternatively, reduces the damping) in order for the switching element 400 to oscillate.

In FIG. 4D, there is shown a basic schematic representation of an exemplary oscillator unit 450 according to certain exemplary embodiments. As shown, the switching element 400 is coupled in series to a current-driven switching element (STT) 400.

Thus, by combining an “n-type” NDR element and, for example, a magnetic junction, a tiny and self-perpetuating oscillator is constructed by simply utilizing the intrinsic electrical behavior of an NDR element. Advantageously, this oscillator does not require any inductors or capacitors and, therefore, consumes very little space and relatively less power. As a result, an oscillator circuit of this type is especially useful in high density semiconductor configurations. Such an oscillator can be used in a variety of applications in which very small, high frequency oscillators are used; not just in reservoir computing for a neuromorphic system. Other uses can include, but are not limited to, a radar source for self-driving vehicles or homeland security operations.

Echo State Reservoir Network Comprising NDR-STT-Type Oscillator Units

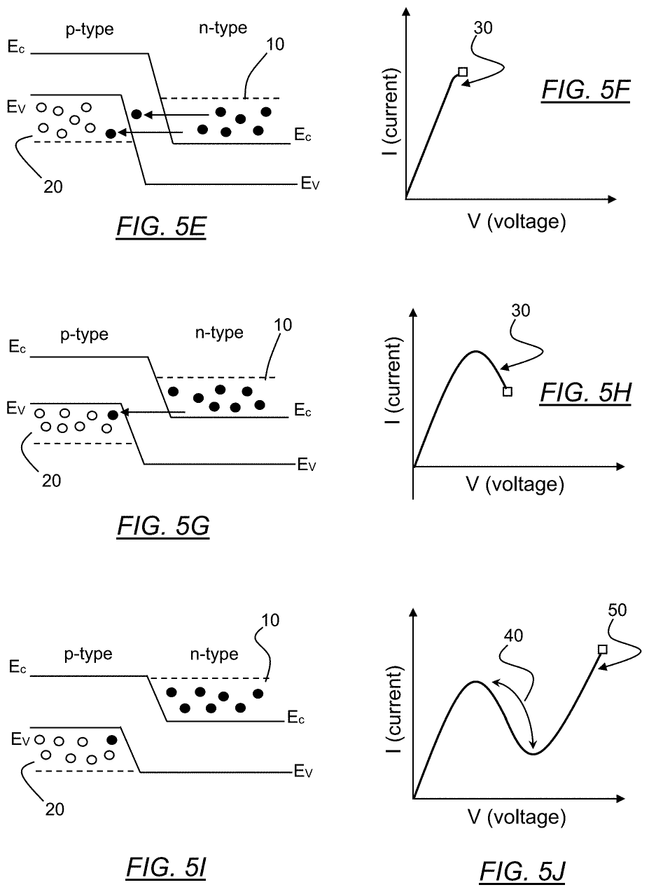

As mentioned above, the NDR-STT-type oscillator described above may be used in a variety of applications calling for a small, high-frequency oscillator component. The following description focuses on the context of reservoir computing as a single non-limiting example. Referring back to FIG. 1, which provides an exemplary embodiment of a reservoir computing system 100, an oscillator scheme, such as the one described with respect to FIGS. 3A-3C and FIGS. 4A-4D, may be integrated into an electrically coupled network of a large number of oscillator units 450 to form a reservoir 110. Due to their compact size and relatively simple structure, the oscillator units 450 may be skillfully fabricated onto a semiconductor wafer in a planar geometry to produce one or more high density networks. As described above, a suitable candidate for the NDR element 300 of the oscillator unit 450 is a tunnel diode due to its characteristic electrical conductivity properties. A tunnel diode is a heavily doped p-n junction diode that experiences the quintessential element of an NDR behavior in which the current decreases as the voltage increases. This is due to the concept of electron tunneling. In a tunnel diode, the p-type semiconductor operates as an anode and the n-type semiconductor acts as a cathode. Specifically, the n-type semiconductor emits or produces electrons and the p-type semiconductor attracts the electrons emitted from the n-type semiconductor. FIG. 5A illustrates the p-n junction of a typical tunnel diode in an unbiased condition wherein no voltage is being applied. As depicted, the conduction band 10 of the n-type material overlaps with the valence band 20 of the p-type material due to the heavy doping. Consequently, the conduction band electrons at the n-region and the valence band electrons at the p-region reside at nearly the same energy level. As indicated in FIG. 5B, no tunnel current exists while the diode is in an unbiased state. Accordingly, upon an increase in temperature, some electrons tunnel from the conduction band 10 of the n-region to the valence band 20 of the p-region. Similarly, some electron holes from the valence band 20 of the p-region tunnel to the conduction band 10 of the n-region. When a small voltage is applied to the tunnel diode and this voltage is less than the built-in voltage of the p-n junction's depletion layer, no forward current flows through the junction. However, as shown in FIG. 5C, a small number of electrons in the conduction band 10 of the n-region will tunnel to the empty states of the valence band 20 of the p-region. Thus, a small application of voltage creates a small forward bias tunnel current 30, as indicated in FIG. 5D. FIG. As shown in FIG. 5E, once the voltage applied to the diode is slightly increased, a large number of free electrons in the n-region and electron holes in the p-region are generated. Therefore, due to the increase in voltage, the overlap of the conduction band 10 of the n-region with the valance band 20 of the p-region is increased. That is to say, the energy level of the conduction band 20 of the n-region becomes nearly equivalent to the energy level of the valance band 10 of the p-region, thereby resulting in a maximum tunnel current flow 30, as depicted in FIG. 5F. Turning now to FIG. 5G, the applied voltage is further increased, which causes the conduction band 20 of the n-region and the valance band 10 of the p-region to be slightly misaligned. However, both bands still overlap to a degree and, therefore, the junction still experiences a flow of electrons from the n-region to the p-region. Accordingly, as depicted in FIG. 5H, the tunnel current 30 begins to decrease, despite the increasing voltage, due to the remaining small current flow. If a voltage increase is continually applied, the tunneling current will cease as the conduction band 20 of the n-region and the valance band 10 of the p-region will no longer overlap, as depicted in FIG. 5I. At this point in time, the tunnel diode will operate in the same manner as a normal p-n junction. If the applied voltage is greater than the built-in potential of the junction's depletion layer, the regular forward current 50 begins to flow, thereby increasing the current through the diode. Accordingly, as shown in FIG. 5J, the characteristic I-V curve of a tunnel diode comprises a negative differential resistance region 40 in which the current decreases amidst an increase in applied voltage.

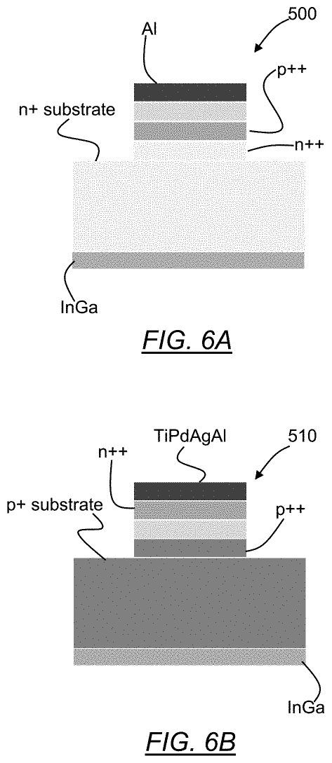

Further advantages in utilizing a tunnel diode as the NDR element 300 of an oscillator unit according to the present disclosure are the ability to fabricate these elements so as to incorporate them into a semiconductor structure, as well as the level of freedom to couple such oscillator units in an effective way to form a high density reservoir network. FIGS. 6A and 6B depict two distinct exemplary embodiments of a tunnel diode structure, i.e., 500 and 510, respectively, which are fabricated on a suitable semiconductor material. For example, a tunnel diode may be fabricated onto a silicon (Si) wafer, or other semiconductor material for higher frequencies. In the specific embodiments of FIGS. 6A and 6B, the wafer material is a gallium (Ga) compound. Such compounds may include, but are not limited to, gallium arsenide and gallium antimonide. A tunnel diode may also be fabricated using a germanium (Ge) material. Further, the tunnel diode fabrication may be conducted or implemented according to, and in compatibility with, CMOS processes. The tunnel diode structure 500 of the embodiment illustrated in FIG. 6A is implemented using an n+ substrate, whereas the tunnel diode structure 510 of the embodiment depicted in FIG. 6B is implemented using a p+ substrate. A switching element 400 may be easily electrically coupled in series with each of these planar tunnel diode elements 500 and 510, in the manner depicted in FIG. 4D. Thereafter, the resulting discrete oscillator units 450 may be electrically coupled together to form one or more random coupling oscillator network(s) 112.

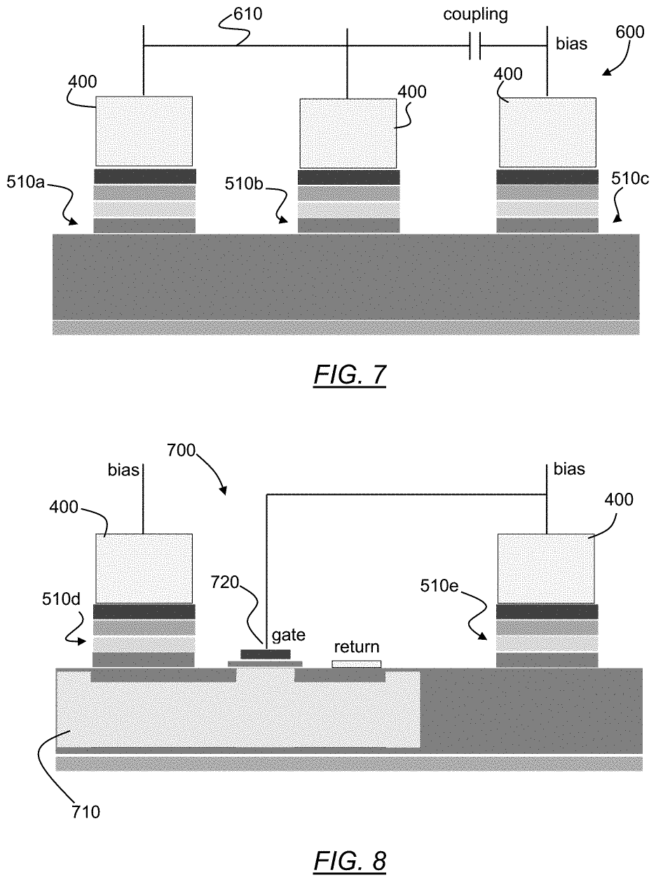

For example, referring now to FIG. 7, it depicts a suitable oscillator coupling configuration 600 according to one exemplary embodiment. For illustrative purposes, FIG. 7 depicts three NDR devices (510a, 510b, and 510c), which, in this particular embodiment, may each comprise a tunnel diode of the p+ substrate type, such as the tunnel diode depicted in FIG. 6B. The NDR devices 510a, 510b, and 510c are, beneficially, closely coupled together. Each NDR device 510a, 510b, and 50c has a respective switching element 400 coupled to it in a series configuration, either, for example, directly on top of the NDR device or to the side of it. Hence, each switching element 400 is biased through the metallization layers (not shown) such that it oscillates according to the methodology that was previously described. Further, the switching elements 400 are connected through a random coupling network. For example, in this particular embodiment, a single coupling wire 610 electrically couples the three oscillator units or cells depicted in this scheme. The coupling can be resistive, capacitive, or inductive. Importantly, this scheme may be expanded in a repetitive manner to couple a large number of oscillator units, including in the thousands.

In another example, FIG. 8 depicts a further suitable oscillator coupling configuration 700 according to another exemplary embodiment. Here, an integrated transistor component 710 (e.g., MOSFET) is used to electrically couple a plurality of oscillator units. For illustrative purposes, FIG. 8 depicts just two coupled oscillator units, whereby each oscillator unit is comprised of a tunnel diode, again of the p+substrate type (marked as 510d and 510e in FIG. 8, respectively), and a respective switching element 400 that is positioned in series with the NDR device. As depicted on the righthand side of FIG. 98, a single oscillator unit goes into the gate terminal 720 of the transistor component 710, whereby the oscillator is modulated such that it produces the desired oscillations.

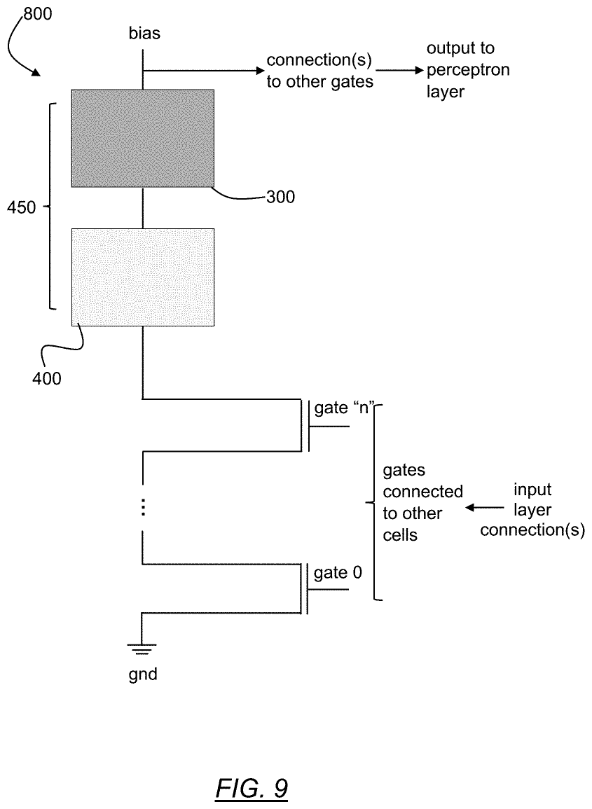

From a system level standpoint, depicted in FIG. 9 is an exemplary embodiment of a fundamental circuit configuration 800 for implementing a dynamic reservoir 110 comprising a multitude of coupled oscillator units into an integrated processing component (e.g., computing memory device). For illustrative purposes, FIG. 9 depicts only a single cell of the integrated processing component, with the understanding that a reservoir network 110 is comprised of a network of intercoupled single cells. Each cell may be comprised of, for example, an oscillator unit 450 that is connected to a series of gates (gate 0 through gate “n,” wherein “n” is an integer greater than 0) that is, in turn, connected in parallel to other cells to achieve an oscillating or looping effect between the cells, thereby creating a vast reservoir. Oscillator unit 450 may be comprised of, for example, an NDR device 300 coupled in series to a switching element 400 according to, for example, the exemplary embodiments depicted in FIGS. 6A-6B, 7, and 8. In addition, one or more of gates 0-“n” may be correspondingly mapped to the inputs of an input layer 104 of the reservoir computing system 100 and, as shown, the NDR device 300 of each oscillator unit 450 may be mapped to an output layer 120 of the reservoir computing system 100 in order for the reservoir output to be utilized in a machine learning stage (e.g., perceptron). Importantly, this coupling scheme and the nature of the oscillator (namely, its NDR properties) result in a one-directional information flow, thereby making it possible to couple a substantial number of oscillator cells without the limitations of, for example, backward propagation and percolation factors.

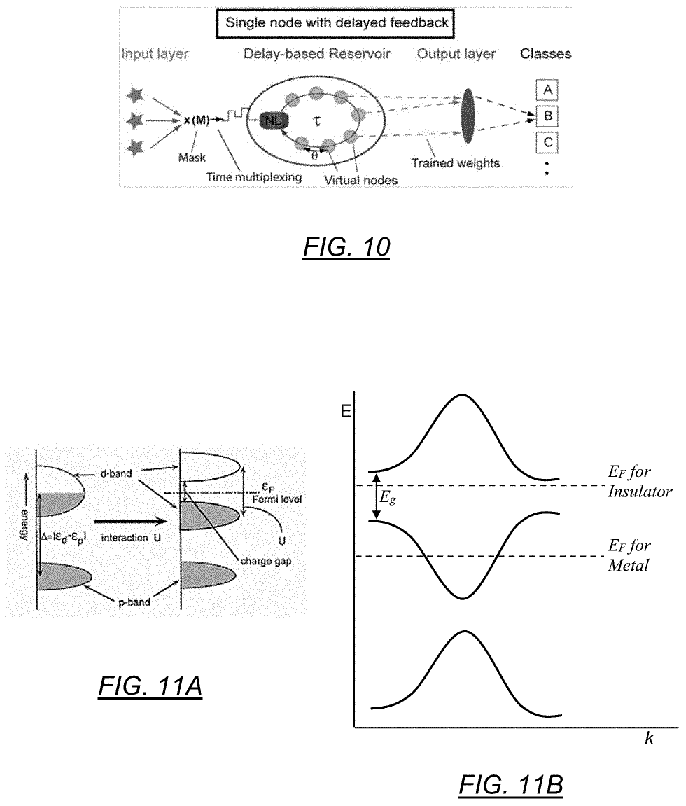

Alternatively, as depicted in FIG. 10, it is also possible to create a virtual reservoir according to another exemplary embodiment, in which a single oscillating element may be used and the input and output signals are time multiplexed. According to this system configuration, there is comparatively a reduced number of oscillators, further resulting in a reduced throughput and reverberating time. As such, this particular system concept of a multiplexed reservoir could be useful in applications having a very low data rate, such as an Internet-of-Things (IoT) application (e.g., to detect an irregularity in an on-line ECG monitor signal).

Echo State Reservoir Network Using Mott Insulator Materials

As mentioned above, different types of oscillator components may be utilized to comprise a dynamic reservoir 110 of a reservoir computing system 100. For example, recent discoveries in the behavior of certain complex metal oxides, such as Mott insulators, which are capable of performing spontaneous metal-insulator-metal (MIM) transitions when under the application of an electric field or a temperature that is at, or is within a, critical threshold or threshold range, and improvements in their constructions, have led to exploring the applicability of these complex oxides to systems of coupled nano-scale oscillators, such as the reservoir networks.

Mott insulators are materials that are nearly metallic but are poor conductors due to correlations in their electronic structure. Electrical insulators or poor electrical conductors comprise an energy gap, E_{g}, as shown in FIGS. 11A-B. By distinction, metals or good electrical conductors have partially filled bands and behave as ideal dielectrics. When undergoing a metal-insulator (MIT) phase transition, a material's electrical resistivity changes by several orders of magnitude, based on certain factors. For example, two parameters that dictate the MIT of a material are electronic correlation strength and electronic band filling. Both of these parameters are influenced by, for example, the applied electric/magnetic fields, pressure, and carrier doping. It is difficult to manipulate the conductivity of certain materials due to the noninteracting band theory. Other materials, however, possess a dominant electronic correlation. Due to the nonlinear behavior of Mott insulator materials, these materials are promising prospects for use in an oscillator construction. One such exemplary class of transition metal oxides are vanadium oxide (VO) compounds, such as V₂O₃.

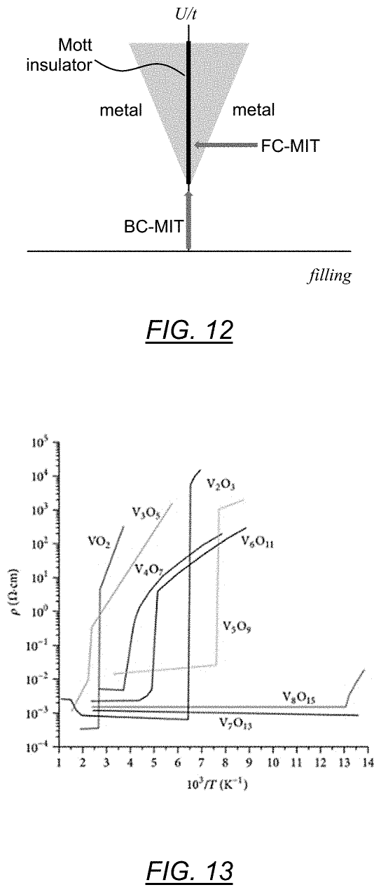

The following discussion provides a brief background with respect to the behavior of Mott insulator materials. On a basic level, the essence of electrical conductivity of a material is the transport of electrons, which requires a non-equilibrium state to occur. According to established theory, metals may be generally distinguished from insulators at an assumed zero temperature condition based on the filling of the electronic bands. With respect to insulators, the highest filled band is completely filled. And for metals, the highest band is only partially filled. More specifically, theoretically the Fermi level lies in a band gap in insulators while the level is inside the band for metals, wherein the formation of the band structure is due to the periodic crystalline lattice structure of the atoms. However, it was later discovered that many transition metal oxides with a partially filled d-electron band were, nonetheless, abysmal conductors and behaved more so as insulators. As such, significant work was conducted in determining the importance of the electron-electron (Coulomb) correlation and the hypothesis that a strong Coulomb repulsion between electrons could be the source of the insulating behavior. And, in progress thereto, an understanding of how an insulator could become a metal by controlling and varying certain parameters has been the subject of many studies and experimentation. The insulating phase and its fluctuations in metals are fundamental features of strongly correlated electrons. Illustrated in FIG. 12 is the metal-insulator phase transition (MIT), according to the Hubbard model in the plane of U/t and filling n. As indicated, the shaded area is principally metallic, but experiences a metal-insulator phase transition in which electron carriers become easily localized by extrinsic forces, including randomness and electron-lattice coupling. In addition, two routes for this transition include filling-control MIT (FC-MIT) and bandwidth-control MIT (BC-MIT). According to the Mott theory, in a lattice model with a single electronic orbital on each site, a single band would be formed from the overlap of atomic orbitals in this system without electron-electron interactions. Specifically, the band becomes full when two electrons, one with spin-up and the other with spin-down, occupy each site. However, in the instance in which two electrons sit on the same site, the electrons would experience a large Coulomb repulsion, thereby splitting the band in two—i.e., a lower band formed from electrons that occupied an empty site and an upper band that is formed from electrons that occupied a site already taken by another electron. As a result, with one electron per site, the lower band is full, thereby constituting an insulator. According to Mott's original formulation, existence of the insulator did not depend on whether the system was magnetic or not. Further study, such as the Slater model, attributes the origin of the insulating behavior to magnetic ordering such as the antiferromagnetic long-range order, which might explain certain Mott insulators that have magnetic ordering at zero temperature. Nonetheless, there exist several examples of a Mott insulator having a spin excitation gap without magnetic order. Also of a challenging subject to understand and manipulate are the metallic phases existing near the Mott insulator transition wherein fluctuations of the spin, charge, and orbital correlations are strong and sometimes critically enhanced toward the MIT, if the transition is continuous or weakly first order. The metallic phase(s) with strong fluctuations are responsible for the mass enhancement of, for example, V₂O₃.

Taking vanadium oxide (VO2) compounds of different oxidation states as an example material, the metal-insulator transition (MIT) typically occurs at a temperature that is slightly above room temperature, i.e., at approximately 340K. Exhibited at this phase transition is an abrupt and substantial change in conductivity, reaching five orders in magnitude, and a simultaneous structural change. Further, a variety of external stimuli can trigger this phase transition in an exceedingly quick manner. In fact, thermal, electrical, optical and mechanical strain are all examples of external stimuli that can trigger this phase transition and on a femto-second time scale. Accordingly, this large and ultra-fast change in electrical conductivity associated with this phase transition establishes vanadium oxide compounds as particularly appealing materials for producing an oscillatory behavior if harnessed effectively. In certain constructions, a VO device will exhibit a non-hysteretic phenomenon in which, when it is subjected to a “critical” electric field at a threshold magnitude or within a specific range of magnitude, an increase in electrical conductivity will, according to the VO device's material properties, produce a simultaneous non-linearity (e.g., a reduction) in the electric field across the device. By utilizing the appropriate circuit elements, such as one or more resistors, the conductivity and electric field across the VO device can be made to modulate one another such that the VO device will switch between a hysteretic and a non-hysteretic phase transition in a periodic fashion, in a series of sustained oscillations.

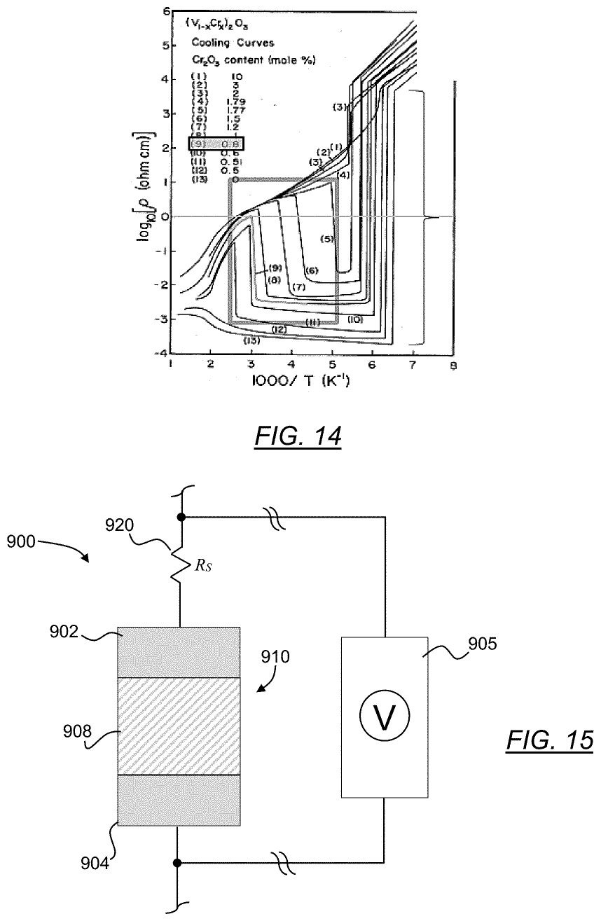

As discussed above, small imposed changes to the electric field, the stress, the strain, temperature, etc. of a transition metal oxide can induce the MIT phase and lead to large changes in resistance. FIG. 13 depicts this phenomenon with respect to several vanadium oxide (VO) compound species. Resistance and transition temperature can also be controlled by doping, as illustrated in FIG. 14 with respect to an exemplary compound (e.g., chromium doped (Cr-doped) insulator device).

An exemplary embodiment of a simple oscillator circuit 900 incorporating a VO-based device 910 is depicted in general terms in the high-level circuit schematic representation that is shown in FIG. 15. Here, the VO device 910 is a two-terminal device (shown in cross-section) placed in series with a resistor (R_{S}) 920. In this particular embodiment, the VO device 910 is comprised of a first electrode 902, a second electrode 904, and a VO-based material 908 that is disposed between the first and second electrodes 902, 904. Although the present disclosure specifies the use of a VO-based material 908 as one illustrative material that, under certain operating conditions, experiences a non-linear behavior, any suitable transition metal oxide with properties that exhibit a non-linear (e.g., NDR) behavior can be used. According to some embodiments, the VO-based material 908 may be fabricating using one or more ultra-thin VO₂ films, with each film having a thickness of, for example, 10 nm to 20 nm, wherein the VO₂ films may be epitaxially grown on a suitable substrate material. Additionally, in this particular embodiment, the VO device 910 and resistor 920 are electrically connected to a variable voltage source (V) 905.

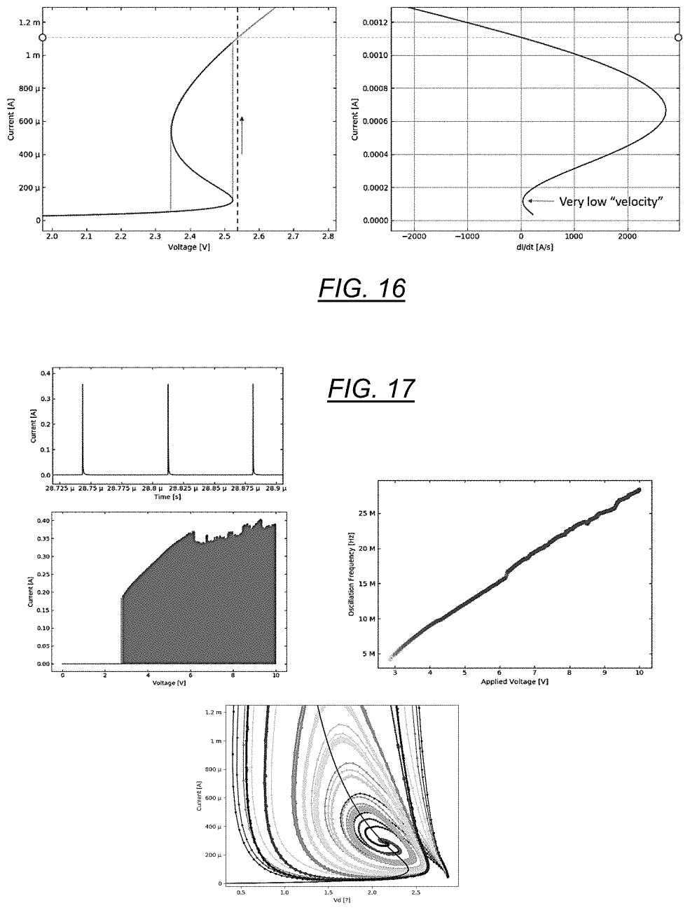

Referring now to FIG. 16, there is shown examples of the non-linear behavior as exhibited by a transition metal oxide element (e.g., Mott insulator) that is implemented, for example, according to the circuit embodiment 900 of FIG. 15, from the perspective of its corresponding I-V curve. Further, the several curves depicted in the plot graphs in FIG. 17 illustrate the operation of an oscillator circuit comprising a V₂O₃ device, such as with respect to the circuit embodiment 900 of FIG. 15, from various viewpoints such as, for example, the oscillation frequency as a function of the applied voltage. The oscillatory behavior may be observed experimentally during a direct current (DC) voltage sweep once an applied voltage is above a certain threshold. As indicated, the oscillation frequency increases with higher applied voltage.

In a similar manner to the network configuration described above using NDR-type oscillators, a network of oscillators may be constructed using the oscillator components just described that comprise a transition metal oxide (e.g., Mott insulator), including with respect to the time-multiplexed reservoir network configuration according to, for example, the exemplary embodiment of FIG. 10.

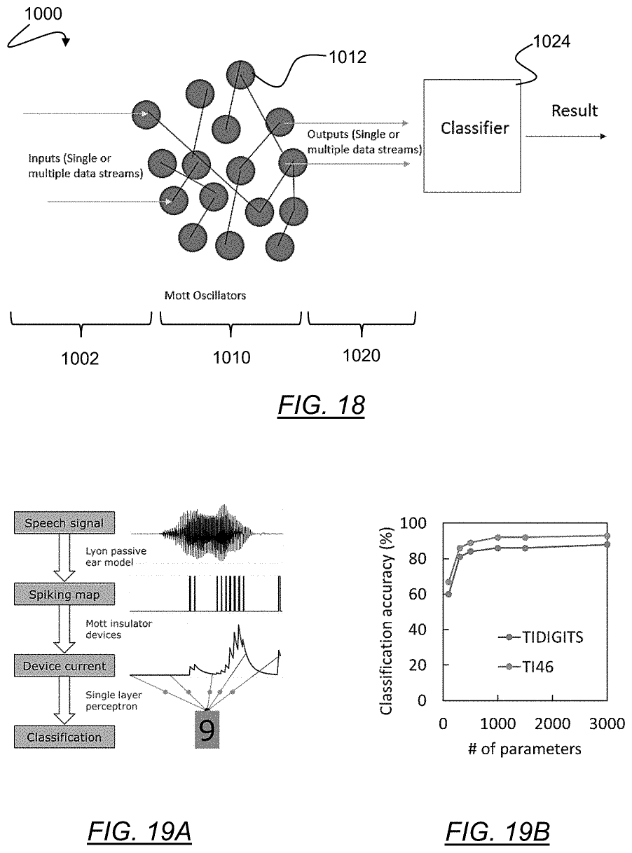

FIG. 18 generally illustrates, according to an exemplary embodiment, a reservoir computing system 1000 comprised of a reservoir 1010 having a network of oscillators 1012, wherein the reservoir 1010 receives input (single or multiple data streams) from an input layer 1002. Oscillators 1012 are comprised of substantially metallic, non-conductive devices, such as transition metal oxides (e.g., Mott insulators), that exhibit oscillatory behavior in the temporal domain. Further, output signal(s) from the reservoir 1010 are propagated to a machine learning stage 1024 via an output layer 1020 of reservoir 1010, wherein the machine learning stage may comprise a perceptron.

Reservoir Computing Applications for Signal Propagation Channels

As previously mentioned, a reservoir computing implementation provides a powerful channel equalization and decoder solution at relatively low cost to improve the accuracy and attenuation of any binary-to-analog signal transmission channel (e.g., recording channel, hard drive, radio channel, integrated optical transmission channel, WiFi multi-pass propagation pathway, and electrical transmission cables that comprise, for example, copper wire). According to exemplary embodiments, a reservoir may be incorporated as a component of the channel, wherein the reservoir may be, but is not limited to, a type comprising one or more networks of oscillators, such as the oscillator networks of the present disclosure, to provide a low latency, energy efficient channel decoder with respect to an incoming bit-sequence data stream. The reservoir may be of any type that pulses in response to a pulse such that it behaves in congruity with brain-like activity.

The following description surveys the application of a reservoir computing machine-learning mechanism to three exemplary tasks.

Beginning with spoken digital recognition, FIG. 19A generally illustrates a training procedure according to the principles of the present disclosure. Suitable isolated spoken digit (0-9) speech may be generated or obtained from a suitable source, such as TI46 and TIDIGITS datasets. In some embodiments, the system first preprocesses speech signals using Lyon's passive ear model into cochlea grams (e.g., firing probability map of neurons at different frequency channels at different time steps). The system may then digitize the four (4) speech signals into spike maps. In the example embodiment, 50 Mott insulators devices were used in parallel to process the spiking sequence from each frequency channel in the spiking map. The system may, for example, use time multiplexing and divide a temporal device current response into several equidistance bins, to generate state vectors by obtaining the analog values at the end of each bin for subsequent training based on a single layer perceptron. As a single layer perceptron is very easy to train and is the only part of the system that needs to be trained, the reservoir computing system described herein may provide advantages with respect to online fast learning when integrated with mobile computing devices. As is generally illustrated in FIG. 19B, with a reasonable number of training parameters, the system may have a test accuracy for spoken digit classification up to reach 93% for the TI46 dataset and 88% for the TIDIGITS dataset.

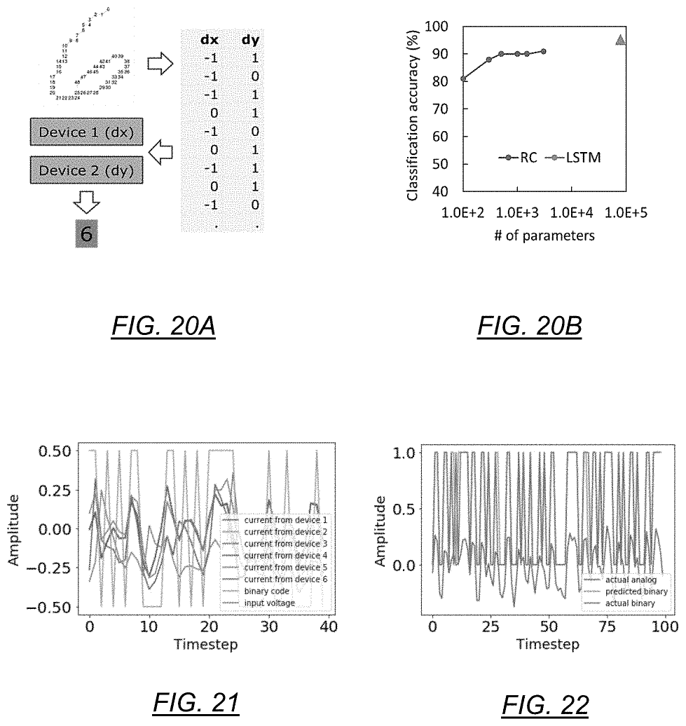

Referring now to FIGS. 20A-B, we investigate the task of MNIST stroke sequence classification. In some embodiments, the system may be configured to recognize handwritten digits using Mott insulator devices (e.g., achieving testing accuracy of 91% with less than 3k training parameters). In some embodiments, the system includes two Mott insulator devices configured to nonlinearly transform input motion vectors in the x and y direction respectively for the MNIST stroke sequences. Accordingly, the system may be configured to use orders of magnitude of fewer training parameters than typical systems, while achieving LSTM based MNIST stroke sequence recognition with accuracy similar to typical systems.

Further, we review the task of HDD channel decoding. Typically, processing of very large bandwidth data streams often requires processing with very low latency. Such data streams may include radar, video streams, time series, analog and digital data streams that are present in memory and storage systems, and other suitable data streams. Due to current technologies, such data channels have reached extremely high data rates and may require processing of multiple streams of data at the same time (MIMO systems). The underlying channel models have also grown in complexity, as well as channel decoders, which are very complex components that require substantial amounts of energy. Thus, rather than using the mainstream method of digital signal processing, a reservoir computing system, such as those described herein, may be configured to be part of a recording channel. FIG. 21 illustrates several example HDD channel data streams, including an expected binary sequence and an analog baud rate waveform after having been put through an anti-aliasing filter. Accordingly, the channel decoder converts the analog sequence into the binary code. In some embodiments, a reservoir computing system, including the exemplary systems described herein, may be configured to convert the analog sequence into the binary code. Thus, a possible training approach for the system may include feeding the input voltage representing the analog sequence to the metallic, non-conductive insulator devices (e.g., Mott insulators) of a reservoir in order to obtain the analog current waveform by taking nearby values on the current waveform as the training inputs provided to a single layer perceptron, with the training output target being 0 or 1 in the binary sequence (see example FIG. 22).

In some embodiments, bit error rates (BER) as low as 0.067 may achieved using the system. For example, the system may include six (6) metallic, non-conductive insulator device oscillators (e.g., Mott insulators) in the reservoir while only 1200 training parameters may be provided to the system, which may result in BER as low as 0.067. In some embodiments, further error correction code (ECC) may be used with the system to further reduce the BER.

Feedback Mechanisms for Echo State Network Gain Control

Irrespective of the precise type of oscillator that is utilized in a reservoir computing system, the reservoir components are particularly susceptible to undesirable variations and interferences due their analog nature. Unlike digital logic systems, analog systems have significantly tighter tolerance margins. Accordingly, it is critically important to be able to finely control and optimize the operating conditions, parameters, performance, and accuracy of the reservoir system, especially in real time. Paramount to the effectiveness of using a reservoir computing system to perform any task is the ability to quickly and effectively detect when the reservoir system is experiencing an operational issue that is outside of pre-determined and acceptable tolerance margins and, in response to the issue detection, automatically tune or adjust a specific operating condition or parameter in order to correct, mitigate or compensate for the detected operational issue. Furthermore, certain metrics of a reservoir computing system's performance may be more or less crucial depending on the particular task to which the reservoir computing system is being applied. Additionally, depending on different characteristics of a particular reservoir computing system, including the type of oscillator being used, the pivotal operating parameters necessary for peak performance and the exact indicia of a problem will vary. Accordingly, there is a myriad of beneficial approaches to incorporating a feedback control mechanism into a reservoir computing system. Several non-limiting examples, and certain considerations, are illustrated by the following exemplary embodiments, each aimed at tightly controlling relevant parameters in order to achieve an exact control of the system bias, thereby optimizing the oscillation amplitude and obtaining reproducible behavior. This is particularly important in machine learning applications.

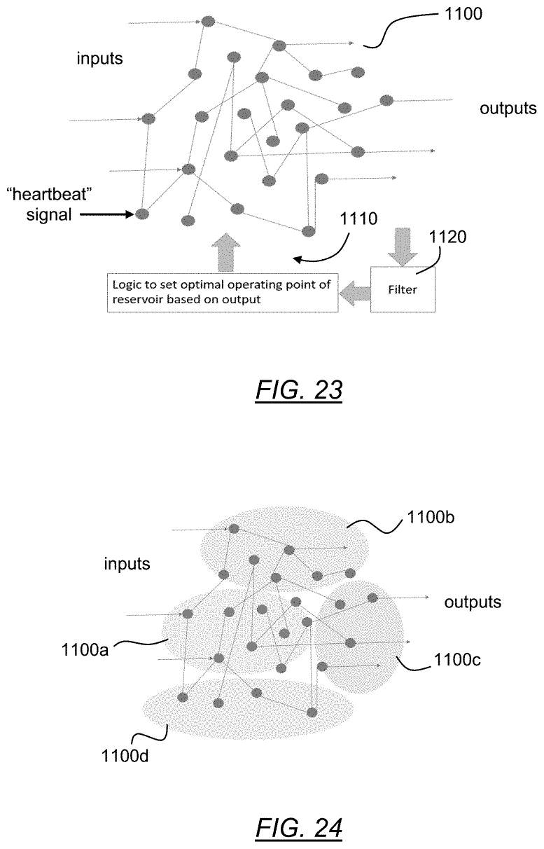

In FIG. 23, there is generally depicted a reservoir 1100 of a representative reservoir computing system, wherein the reservoir 1100 comprises a random network of oscillators and receives input data and produces one or more output signals. Exemplary embodiments of a reservoir were previously described in reference to FIGS. 9 and 18, for example. As shown in FIG. 23, an output of the reservoir 1100 (which may be generated in response to a specific input control signal) is supplied to a feedback loop 1110 that comprises logic circuitry that establishes and maintains the optimal operating point (or parameters) of the reservoir 1100 based upon the received output. Such parameters may include, but are not limited to, temperature, bias current/voltage, optical illumination, link strength between the reservoir nodes, etc. In order to determine the optimal operating point (or parameters) of reservoir 1100, a filter 1120 may be incorporated into feedback loop 1110 at the reservoir output, wherein filter 1120 is capable of measuring, or otherwise detecting, a parameter of the output and determining if, for example, the parameter is within a proper range or at a specific threshold that is consistent with optimal operation. For example, the filter 1120 could measure an output amplitude (in, for example, a speech recognition task), a noise level of the output, a frequency distribution of the output (in which, for example, a high frequency distribution signifies a need to reduce the current), phase, and a ratio of frequencies, etc. In a more complex system, filter 1120 may comprise a machine learning tool that can be used to, for example, detect spelling errors or inaccuracies in a letter sequence, which is information that can be used to tune the reservoir's operation.

Referring now to FIG. 24, it may be advantageous according to certain exemplary embodiments to define separate regions (e.g., regions 1100a, 1100b, 1100c, and 1100d) of reservoir 1100, wherein each of the regions is individually monitored and tuned according, for example, to the feedback mechanism just described. More specifically, each region has its own control logic and driver to control the operating parameters relevant to its respective region. Additionally, each region may comprise individual elements (e.g., voltage supply, thermometer, heater, resistor network) specific to tuning that region for its optimal operating point. This approach captures device variations that may be the result of, for example, gradients that were produced during the wafer fabrication process, and allows the system to narrowly address any issues acute to a specific region and not the entire reservoir as a whole, thereby efficiently ensuring that the entire reservoir 1100 is functioning at its optimal operating point.

Another vital aspect of optimizing the stability and operation of the reservoir is to take into consideration the time period of the network's associated memory. For many applications, the period duration should allow for the reservoir to remember far enough into the past to solve the current task at hand, but not any further. For example, if the task is to decode signals with a block length of 1 μs, it does not make sense to have a memory that is much longer than 1 μs. Accordingly, the internal time scale of the reservoir can be tuned according to the feedback mechanism such that, after a desired time that is commensurate with the application, the output has decayed to a small fraction such that events in the past do not influence the current task.

In addition, in circumstances in which there may not be a regular or continuing input signal to the reservoir in order for the reservoir to in turn produce an output with which the feedback mechanism can operate, a mock or “heartbeat” signal may be injected as an input into the reservoir, as shown in FIG. 23, to ensure that the reservoir will produce an output for the feedback mechanism to actively operate on. This mock signal may include, for example, pulse trains, sinewaves, or more complex waveforms, and can be either a persistent or an intermittent signal. Further, the mock signal should be similar to the type of data signal that the reservoir system is used to analyzing in order that the feedback mechanism is tuning the reservoir system according to its actual duties despite operating off of a mock signal. Although the mock signal and expected signal should be of a similar data type, they should not be identical (e.g., use the same data set) such that the feedback mechanism can distinguish between the two signals. Accordingly, the feedback loop can be tuned to the analysis of the mock signal, or the mock signal itself can be tuned in response to the output. Further, the type of mock signal may be chosen in response to, or based upon, a desired operation of the reservoir as a proactive mechanism to ready or steer the reservoir in the direction of the desired task by choosing a mock signal that is more optimal for the desired task. Information indicating the type of mock signal best suited for a desired or an approaching task may come from what is discovered by the feedback mechanism at the reservoir output. For example, filter 1120 might sense a recent increase in data consisting of digits and, therefore, initiate the selection of a mock signal that improves the system's sensitivity to digit recognition.

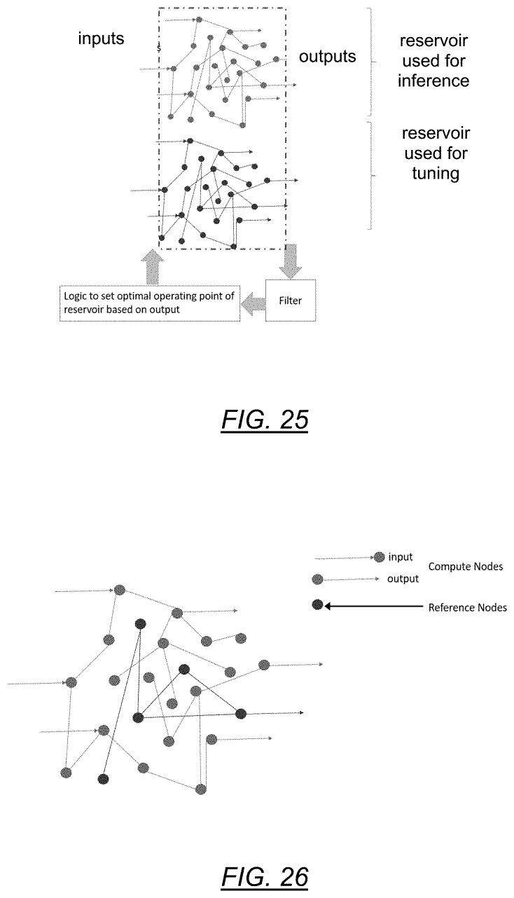

Alternatively, rather than employing a mock signal that must be, in some manner, distinguishable from an expected input data signal, the feedback and tuning mechanism could instead be applied to two identical reservoirs in parallel, such that the test signal used for the feedback and tuning mechanism can be applied to one of the two reservoirs that is dedicated specifically to the tuning operation, wherein the other of the two reservoirs is dedicated to the inference operation. In this way, the test signal can be identical to the original data and both reservoirs can be tuned together if indicated by the feedback mechanism. FIG. 25 illustrates an exemplary embodiment with respect to this concept. A similar approach is depicted in the exemplary embodiment of FIG. 26, which comprises a bipartite reservoir having interleaved components that is, in essence, the equivalent of having a second reservoir inside of a first reservoir. Accordingly, the interleaved components will react and adjust in the same manner, thereby allowing for very close matching of the device variation when employing a test input signal.

To promote efficiency and power conservancy in the optimization approaches discussed above, the reference reservoir may be operated only part time. In addition, the operating parameters determined to produce an optimal operating point for a particular reservoir may be stored in an external memory to quickly restore a desired configuration without the necessity of repeating the feedback/tuning optimization procedure. Further, a mechanism could be provided for selecting the best operating parameters from memory depending on an external input, including the temperature, desired latency, power consumption, and type of data to be classified.

The above discussion is meant to be illustrative of the principles and various embodiments of the present invention. Numerous variations and modifications will become apparent to those skilled in the art once the above disclosure is fully appreciated, and may be employed without departing from the scope of the disclosure, limited only by any practical limitations related to the materials and physical principles of the devices that are described. It is intended that the following claims be interpreted to embrace all such variations and modifications.

What is claimed is:

1. A signal-producing oscillating circuit, comprising:
a negative differential resistance (NDR) device characterized by a current-voltage curve that comprises a region in which an increasing input voltage corresponds to a decreasing current condition; and
a current-driven switching element electrically coupled to the negative differential resistance (NDR) device and having a resistance-switching state that, in response to the decreasing current condition, produces an increase in current that induces the circuit to oscillate and produce an oscillatory signal.

2. The signal-producing oscillator circuit according to claim 1, wherein the current-driven switching element is electrically coupled in series with the negative differential resistance (NDR) device.

3. The signal-producing oscillator circuit according to claim 1, wherein the negative differential resistance (NDR) device comprises a tunnel diode.

4. The signal-producing oscillator circuit according to claim 1, further comprising a bias voltage supply to apply an input voltage to the negative differential resistance (NDR) device.

5. A reservoir, comprising a plurality of integrated oscillator components coupled to one another in a fixed, random network, wherein each of the oscillator components is comprised of a device characterized by a current-voltage curve that comprises a region of non-linear behavior.

6. The reservoir according to claim 5, wherein each of the plurality of oscillator components comprises:
a negative differential resistance (NDR) device characterized by a current-voltage curve that comprises a region in which an increasing input voltage corresponds to a decreasing current condition; and
a current-driven switching element electrically coupled to the negative differential resistance (NDR) device and having a resistance-switching state that, in response to the decreasing current condition, produces an increase in current that induces the circuit to oscillate and produce an oscillatory signal.

7. The reservoir according to claim 6, wherein the negative differential resistance (NDR) device comprises a tunnel diode.

8. The reservoir according to claim 5, wherein each of the plurality of oscillator components comprises a substantially metallic and non-conductive insulator material.

9. The reservoir according to claim 8, wherein the insulator material is comprised of a Mott insulator material.

10. The reservoir according to claim 8, wherein the insulator material comprises a transition metal oxide that includes a vanadium oxide compound.

11. A reservoir computing system, comprising:
an input layer configured to receive input data from a signal propagation channel and to convert the input data into one or more fixed input values;
a reservoir configured to receive the one or more fixed input values and to generate one of a set of trained output values; and
an output layer configured to receive the one of the set of trained output values and to generate one of at least a probability distribution based on the one of the set of trained output values.

12. The reservoir computing system according to claim 11, further comprising a single layer perceptron.

13. The reservoir computing system according to claim 11, wherein the signal propagation channel is one of:
a recording channel;
an optical transmission channel;
a hard drive channel;
a communication channel;
a wireless transmission channel;
an acoustic channel; and
an electric wire transmission channel.

14. The reservoir computing system according to claim 11, wherein:
the input data is comprised of a symbol sequence; and
the reservoir is configured to operate as a channel decoder or equalizer.

15. The reservoir computing system according to claim 11, wherein the reservoir comprises a plurality of integrated oscillator components that are coupled to one another in a fixed, random network.

16. The reservoir computing system according to claim 15, wherein each of the plurality of oscillator components comprises:
a negative differential resistance (NDR) device characterized by a current-voltage curve that comprises a region in which an increasing input voltage corresponds to a decreasing current condition;
a current-driven switching element electrically coupled to the negative differential resistance (NDR) device and having a resistance-switching state that, in response to the decreasing current condition, produces an increase in current that induces the circuit to oscillate and produce an oscillatory signal.

17. The reservoir computing system according to claim 16, wherein the negative differential resistance (NDR) device comprises a tunnel diode.

18. The reservoir computing system according to claim 15, wherein each of the plurality of oscillator components comprises a material that is characterized by a non-linear conductive behavior.

19. The reservoir computing system according to claim 18, wherein the insulator material is comprised of a Mott insulator material.

20. The reservoir computing system according to claim 18, wherein the insulator material is a transition metal oxide that includes a vanadium oxide compound.
